(19) United States
(12) Patent Application Publication
(10) Pub. No.: US 2025/0048695 A1
(43) Pub. Date: Feb. 6, 2025

(54) MULTI-GATE FET WITH SELF-ALIGNED TAPERED ACTIVE REGION EDGE

(71) Applicant: INTERNATIONAL BUSINESS MACHINES CORPORATION, ARMONK, NY (US)

(72) Inventors: Reinaldo Vega, Mahopac, NY (US); Takashi Ando, Eastchester, NY (US); James P. Mazza, Saratoga Springs, NY (US); Nicholas Anthony Lanzillo, Wynantskill, NY (US); David Wolpert, Poughkeepsie, NY (US)

(21) Appl. No.: 18/365,989

(22) Filed: Aug. 5, 2023

(51) Int. Cl. H01L 29/08; H01L 21/3065; H01L 29/06; H01L 29/423; H01L 29/66; H01L 29/775

(52) U.S. Cl. CPC H01L 29/0847; H01L 21/3065; H01L 29/0673; H01L 29/42392; H01L 29/66439; H01L 29/775

(57) ABSTRACT

A semiconductor device includes a substrate and a plurality of stacked transistors positioned on the substrate. The transistors include a gate region and a source and drain proximate the gate region. The source and drain includes an overall region and an active region. A thickness of the active region is less than a thickness of the overall region.

### BACKGROUND

### Technical Field

The present disclosure generally relates to semiconductor device fabrication, and more particularly, to a multi-gate Field Effect Transistor with self-aligned tapered active region edge.

### Description of the Related Art

A Field Effect Transistor (FET) typically has a source, a channel, and a drain, where current flows from the source to the drain, and a gate that controls the flow of current through the channel. Field Effect Transistors (FETs) can have a variety of different structures, for example, FinFETs can be formed with the channel extending outward from the substrate, but where the current flows vertically, as compared to a MOSFET with a single planar gate. Depending on the doping of the source and drain, an n-FET or a p-FET may be formed.

The FinFET is a type of MOSFET. The FinFET is a multiple-gate MOSFET device that mitigates the effects of short channels and reduces drain-induced barrier lowering. The “fin” refers to a semiconductor material patterned on a substrate that often has three exposed surfaces that form the narrow channel between source and drain regions. A thin dielectric layer arranged over the fin separates the fin channel from the gate. Because the fin provides a three-dimensional surface for the channel region, a larger channel length can be achieved in a given region of the substrate as opposed to a planar FET device.

As semiconductor devices scale to smaller dimensions, vertical FET devices provide advantages. A vertical FET often comprises an active source/drain region layer arranged on a substrate. A bottom spacer layer is arranged on the active source/drain region layer. The channel region of the FET device is arranged on the bottom spacer layer. The channel region can include any number of shapes including a fin shape.

The gate stack is arranged on the bottom spacer layer and around the channel region. A top spacer layer is arranged on the gate stack. The spacers are used to define the channel region in active areas of a semiconductor substrate located adjacent to the gate.

### SUMMARY

According to an embodiment of the present disclosure, a semiconductor device is provided. The semiconductor device includes a substrate and a transistor positioned on the substrate. The transistor includes a gate region and a source and drain proximate the gate region. The source and drain includes a first region and a second region. The second region includes a width that is less than a width of the first region.

According to another embodiment of the present disclosure, a semiconductor chip device is provided. The semiconductor device includes a substrate. A gate region is supported by the substrate. The gate region includes a first side wall, a first centerline extending axially along a width of the gate region, and a second centerline extending transversely across the first centerline. A source and drain region is positioned transversely to the gate region. The source and drain region includes a second side wall and a third side wall. The second side wall and the third side wall are recessed into the source and drain region from an outer surface of the source and drain region.

According to another embodiment of the present disclosure, a method of manufacturing a semiconductor device is provided. The method includes providing a substrate. A plurality of transistor gate structures are formed on the substrate. A source and drain region is positioned adjacent the plurality of transistor gate structures. Material in the source and drain region is recessed toward a centerline of the source and drain region. A width at a center point of the source and drain region is less than an overall width of the source and drain region.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1A is a schematic top view of a gate and source and drain structure formation for a conventional semiconductor device, consistent with an illustrative embodiment.

FIG. 1B is a schematic top view of a gate and source and drain structure formation for a semiconductor device, consistent with embodiments of the present disclosure, consistent with an illustrative embodiment.

FIG. 1C is a diagrammatic view illustrating an angle of a source and drain region side wall relative to a gate region side wall of the formation of FIG. 1B, consistent with embodiments of the present disclosure.

FIG. 2A is a top view of an initial semiconductor device formation showing a gate cap over a source and drain region epitaxial deposition in a multi-gate transistor formation, according to an embodiment.

FIG. 2B is a cross sectional side view of the semiconductor device formation of FIG. 2A.

FIG. 3A is a top view of the formation of FIG. 2A after an epitaxial cut mask is applied over the source and drain epitaxial region, consistent with an illustrative embodiment.

FIG. 3B is a side view of the formation of FIG. 3A, consistent with an illustrative embodiment.

FIG. 4A is a top view of the formation in FIG. 3A after an epitaxial cut process is applied to the source and drain epitaxial region, consistent with an illustrative embodiment.

FIG. 4B is a side view of the formation of FIG. 4A, consistent with an illustrative embodiment.

FIG. 5A is a top view of the formation in FIG. 4A after an isotropic epitaxial etch process is applied to the source and drain epitaxial region, consistent with an illustrative embodiment.

FIG. 5B is a side view of the formation of FIG. 5A, consistent with an illustrative embodiment.

FIG. 6A is a top view of the formation in FIG. 5A after mask removal and a crystallographic isotropic etching of the source and drain epitaxial region, consistent with an illustrative embodiment.

FIG. 6B is a side view of the formation of FIG. 6A taken along the line B-B′ of FIG. 6A.

FIG. 7A is a top view of the formation in FIG. 6A after application of an interlevel dielectric to the source and drain region and forming a contact element, consistent with an illustrative embodiment.

FIG. 7B is a side view of the formation of FIG. 7A.

### DETAILED DESCRIPTION

### Overview

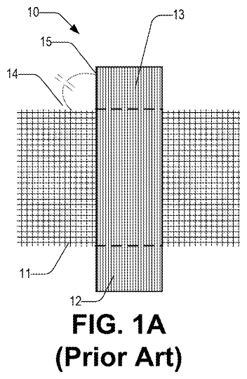

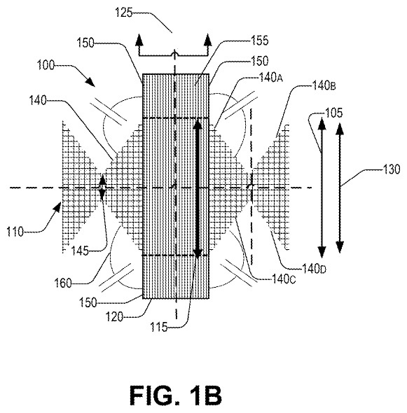

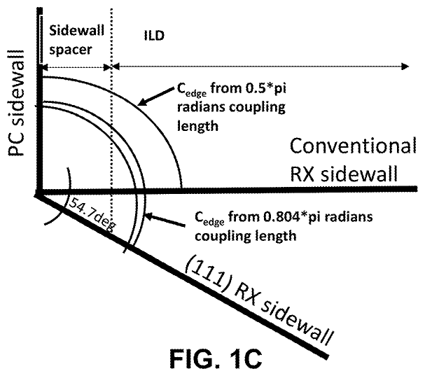

In general, the subject technology reduces the parasitic capacitance in semiconductor devices such as multi-gate transistors and FinFETS. Referring to FIG. 1A, in a conventional transistor device 10, a source and drain region 11 is positioned adjacent a gate region 12. The section of the gate region 12 that overlaps the source and drain region 11 is the active gate region. The sections 13 of the gate region 12 that extend beyond the active gate region provide no benefit to the operation of the transistor device 10; in other words, are inactive gating regions which do not help in switching. Generally speaking, the arrangement of the source and drain region 11 and the gate region 12 are orthogonal to each other. For example, as can be seen in FIGS. 1A and 1C, the side wall 15 of the gate region 12 (labeled as “PC” in FIG. 1C) is generally at a right angle relative to the side wall 14 of the source and drain region 11. While the side wall 15 of the gate region adds little to no value, its presence relative to the side wall 14 of the source and drain region 11 adds a degree of parasitic capacitance (sometimes called the “edge capacitance”). As the scale of transistor elements becomes smaller, the distance between the side wall 15 of the gate region to the side wall 14 of the source and drain region 11 becomes a factor in contributing parasitic capacitance in the transistor device 10.

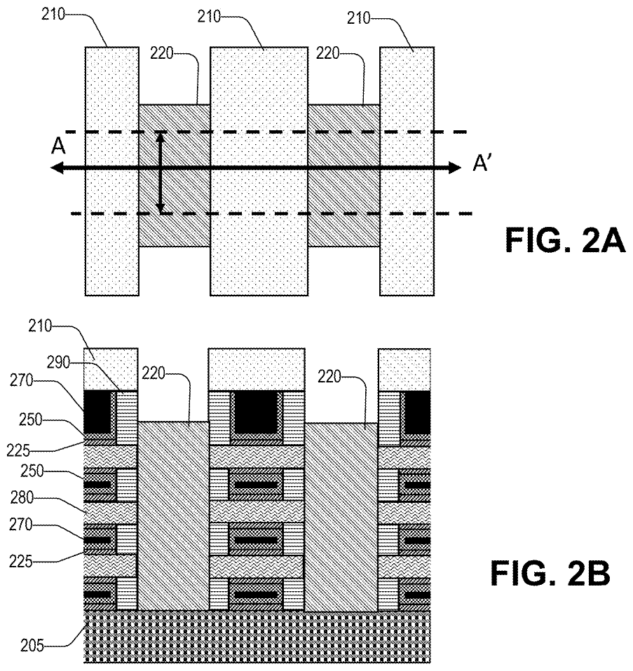

For the sake of brevity, conventional techniques related to semiconductor device and integrated circuit (IC) fabrication may or may not be described in detail herein (for example, the process leading up to the formation shown in FIG. 2B below). Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Definitions

Source and Drain: A region of electron carrying material that acts as terminals in a transistor for the flow of charge.

Gate Region: A region of material in a transistor adjacent the source and drain that controls flow through the source and drain when a voltage is applied.

Inactive Gate Region: A region of gate material that is excess and does not contribute to switching in a transistor. The inactive region may be positioned outside the range of the source and drain.

Self-aligned: The patterning of a structure relative to alignment with another structure.

Substrate: Reference to a substrate may refer to material that provides a support structure to features in or on top of the substrate material. As used below, there may be more than one substrate present in an embodiment shown. Also, since embodiments below are generally shown in cross-section, it should be understood that a substrate for a layer with patterned features may not be visible in the view so as to highlight the features for the layer.

### Example Device Structure

Referring now to FIGS. 1B and 1C, the subject disclosure provides a transistor device 100 that mitigates the parasitic capacitance that can form between the side wall 140 of a source and drain 110 and the side wall 150 of a gate region 120. The transistor device 100 may be a finFET or a multi-gate type device. In an exemplary embodiment, the edge or side wall 140 of the source and drain 110 is recessed inward toward a center of the source and drain 110 region. For example, the source and drain 110 may include a first region 105, (which may be for example, an overall area of the source and drain 110). The source and drain 110 may include a second region 130. An extent of the second region 130 of the source and drain 110 may start from any two points inside the outer surface of the source and drain region 110. The width of the second region 130 may be les than the width of the source and drain 110 as the side wall 140 tapers inward. The second region 130 may include left and right side walls 140. The center point of the source and drain 110 may be located at a centerline of the gate region 120 that runs transverse to a centerline that runs axially in the gate region 120. The side walls 140 of the second region 130 may converge toward a center point of the source and drain 110. For example, with the side wall 150 being considered a first wall, the second region may include a second side wall 140A and a third side wall 140B on a first side of the centerline of the gate region 120 that runs transverse to the centerline that runs axially in the gate region 120. The second side wall 140A and the third side wall 140B may converge toward each other at or proximate the centerline. Some embodiments include a fourth side wall 140c and a fifth side wall 140p that taper inward toward the center of the source and drain region, from the side of the centerline of the gate region that is opposite the side of the centerline that the second side wall and the third side wall taper inward from.

In some embodiments, the pairs of side walls (140A and 140B or 140c and 140D) may be considered a single uninterrupted side wall 140 (on each side of the centerline). The slope for the edge (side wall 140) of the source and drain 110 may be linear while moving away from the intercept point with the gate region 120 that is beyond the active gate area (the inactive gate region 155). As can be seen in FIG. 1B, the distance of the side wall 140 to the intercept with the inactive gate region 155 has increased relative to the distance of analogous surfaces in conventional transistor arrangements (for example, as shown in FIG. 1A). The distance continues to increase as the side wall 140 slopes toward the centerline of the source and drain 110. In some embodiments, the side wall 140 has a nadir and the surface reverses direction with an upward grade that may terminate back to the same level as the intercept with the gate region 120. As shown in FIG. 1B, both of the top and bottom side walls 140 of the source and drain region may be symmetrically recessed inward.

In another embodiment, the subject structure may be viewed in terms of the thickness in areas of the source and drain 110. Straddling lines (the edges defined by side walls 150) define a thickness 125 of the gate region 120. The source and drain 110 may include an overall thickness 115 (as depicted by the double-ended arrow overlaying the gate region 120). In areas of the source and drain 110 that are adjacent to the gate region 120, the side wall 140 may taper symmetrically down or inward from the overall thickness 115, starting from the points adjacent the side wall 150 of the gate region 120. The tapering or receding may end proximate a center point in the distance between a side edge of the gate region 120 and an exterior edge of the source and drain 110. At the center points for each side of the source and drain 110, the second region 130 has a thickness 145 that is less than the overall thickness 115 of the source and drain 110. The thickness 145 of the active region 130 may be self-aligned to the to length of the source and drain; for example, as the length of the source and drain 110 increases, the thickness 145 may decrease. In embodiments with a plurality of gate regions 120, there may also be a dependence on the spacing between adjacent gate regions 120; for example, as the spacing between gate regions 120 increases, the overall length of the source and drain 110 increases. The side wall 140 of the active region 130 may be caved in from or indented from the edges defined by the overall thickness 115 of the source and drain 110. From the two-dimensional perspective offered by FIG. 1B, the resultant shape of the active region 130 may resemble a bow-tie.

As will be appreciated, the structure of the source and drain 110 increases the distance between the side wall 140 of the active region 130 to the side wall 150 of the gate region 120. The effect produces an angle 160 between the side wall 140 and side wall 150 that is greater than 90 degrees and may be less than 180 degrees. In some embodiments, crystallographic etching may be used to recess the active region 130 to produce the angle of the side wall 140. In one embodiment, the side wall 140 may be provided by etching down the material in the source and drain 110 approximately 54.7 degrees more beyond 90 degrees (See FIG. 1C). The side wall 140 may terminate on a crystallographic plane having a Miller index of (1,1,1).

### Example Methodology of Manufacture

In the following, a process describes a general method of forming a semiconductor device with a tapered source and drain edge. Embodiments increase the distance between the source and drain active region and adjacent surfaces of the gate non-active region (when compared to conventional formation of gates and source and drain elements), which reduce parasitic capacitance in the device. The process tapers edges of the active region inward to form for example, bow-tie shaped source and drain areas. FIGS. 2A and 2B-7A and 7B a illustrate fabrication process for manufacturing a semiconductor device with a self-aligned tapered active region edge.

The fabrication of the devices described herein below can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, device 100 can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

In one embodiment, the base semiconductor substrate 205 may be a bulk semiconductor substrate formed of, for example, silicon, or other types of semiconductor substrate materials that are commonly used in bulk semiconductor fabrication such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

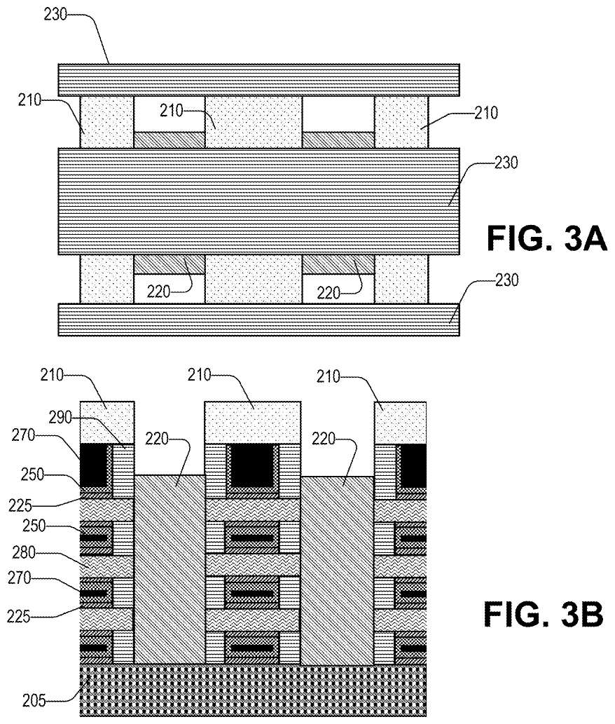

Referring now to FIGS. 2A and 2B, an initial semiconductor device formation is shown. FIG. 2B shows the side view along the cross-section taken along line A-A′ in FIG. 2A. FIGS. 3B, 4B, and 5B are show the same side view tracking the formation steps in FIGS. 3A, 4A, and 5A. In the example shown, a nanosheet type, multi-gate vertical FinFET transistor is being manufactured. The initial formation includes multiple nanosheet channels 280 stacked vertically. The process may have used a replacement metal gate (RMG) technique that processed the transistor up to the inclusion of metal in the gate areas. Each transistor includes a gate 270, surrounded by a dielectric 250 and spacers 290. An interlayer dielectric 225 (for example, an oxide) separates the gates 270 from nanosheet channels 280 positioned in between successively stacked gates 270.

In the initial formation shown, a semiconductor material epitaxial growth 220 is deposited in between adjacent fins that will be the source and drain. The source and drain epitaxial growth may be wider than the eventual source and drain active region (represented by the width between the two dashed lines) due to overgrowth of the semiconductor material epitaxial growth 220. A gate cap 210 layer may be applied over the nanosheet stacks of each fin.

FIGS. 3A and 3B show preparation of an epitaxial cut mask to the formation in FIGS. 2A and 2B. A cut mask 230 may be applied over the epitaxial growth 220 and over edges of the gate cap 210. As will be appreciated, when growing epitaxial crystals in a fin or nanosheet structure, the growth is not rectangular. The openings that remain between layers of the cut mask 230 define the areas where excess epitaxial growth 220 will be removed to define the active region of the source and drain.

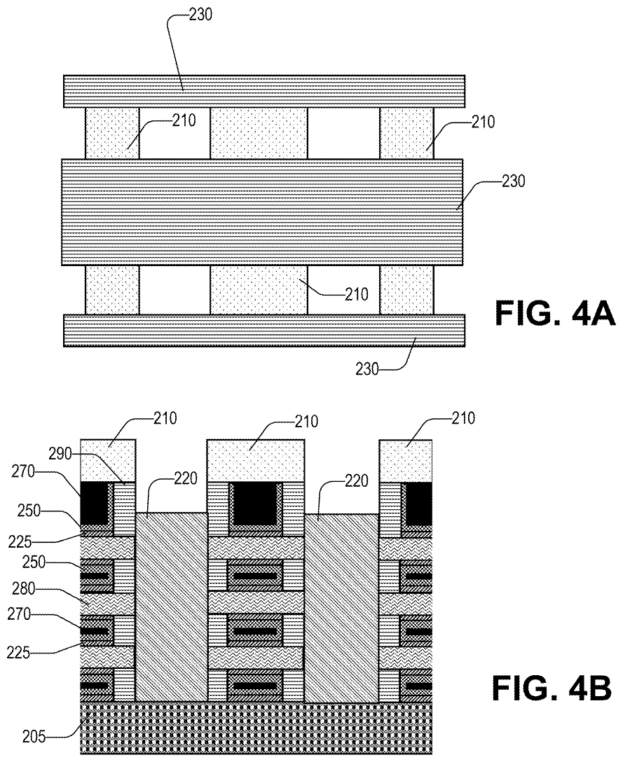

FIGS. 4A and 4B show application of an epitaxial cut to the formation in FIGS. 3A and 3B. An anisotropic cut may be performed. Embodiments may use for example, a reactive ion etching (RIE) process. As can be seen in FIG. 4A, the epitaxial growth 220 is cut back to the edges defined by the cut mask 230. The epitaxial cut defines a vertical portion of the source and drain side wall in anticipation of an inward taper etch. While not necessary, those of skill on the art may appreciate that the epitaxial cut provides an improved capacitive benefit since the epitaxial cut pushes the epitaxial boundary inward toward the active region edge (which itself reduces capacitance somewhat), while also increasing the height over which the inward taper can be present.

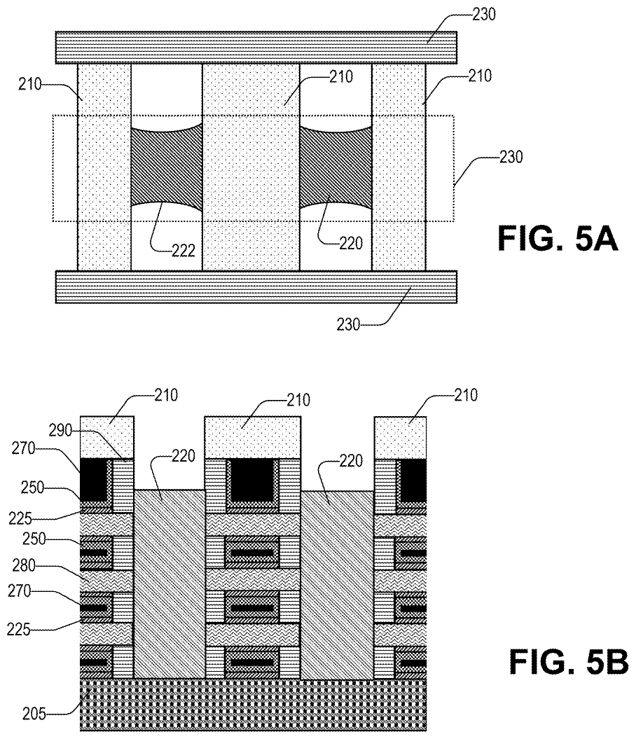

FIGS. 5A and 5B show performance of an isotropic etch (for example, using a RIE process) to the epitaxial growth 220. As can be seen in FIG. 5A, the isotropic etch recedes the epitaxial growth 220 forming a caved in or curved surface 222. The isotropic etch may prepare the curved surface 222 for a crystallographic etch process. Forming, for example, (1,1,1) crystal plane facets may benefit from first performing an isotropic etch. The isotropic etch exposes all crystal orientations along the etched surface.

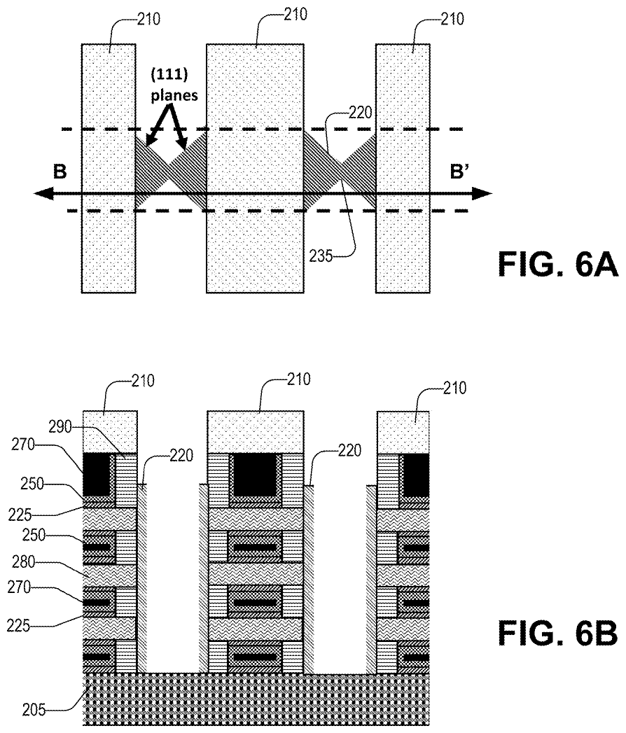

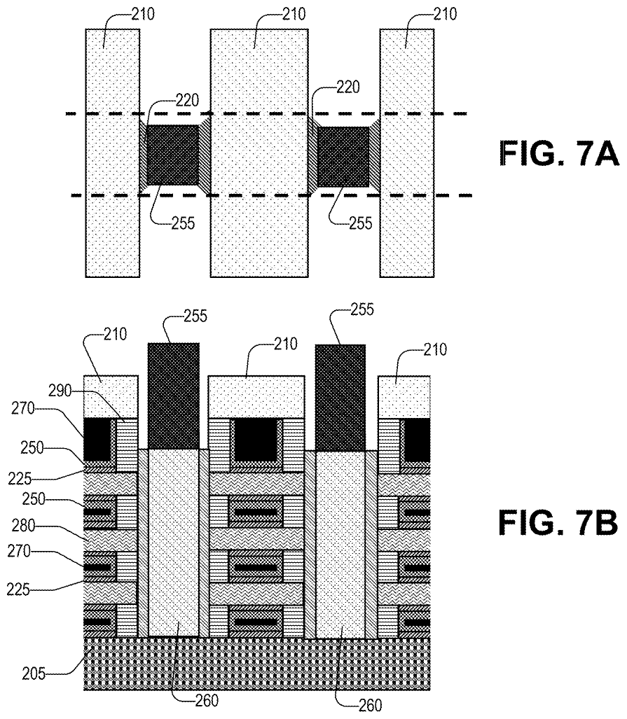

FIGS. 6A and 6B show the performance of a crystallographic isotropic etch to the epitaxial growth 220. FIGS. 6B and 7B show the side view perspective along cross section B-B′. A crystallographic etch (e.g., using NH₄OH), may be applied to the isotropically etched surface. All crystal orientations may etch away except for the facets that self-terminate on (1,1,1) planes of the Miller index, leaving behind for example, the triangle-like indent viewed in FIG. 6A. As may be appreciated, the crystallographic isotropic etch provides a uniform and linear inward tapering of the crystalline growth. The tapering may occur from edges of the epitaxial growth 220 that are adjacent the edges of the cut mask 230. The tapering may be at its greatest at the midpoint between edges of the cut mask 230. From the perspective shown in FIG. 6A, each section of the epitaxial growth 220 between mask sections resembles two triangles or pyramids adjoined at apexes. While the embodiment shows tapering down to a neck 235, it will be understood that the amount of crystallographic etching applied is controllable to produce a desired thickness at the neck 235 all the way down to points for each apex if desired. When the degree of tapering is reached, the cut mask 230 may be removed.

FIGS. 7A and 7B show the application of an interlevel dielectric 260 in the open areas adjacent the epitaxial growth 220. In some embodiments, a metal contact 255 may be formed connecting to the epitaxial growth 220 that is now tapered and will serve as the source and drain for the transistor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate; and
a transistor positioned on the substrate, wherein the transistor includes:
a gate region; and
a source and drain proximate the gate region, including a first region of the source and drain and a second region of the source and drain, wherein the second region has a width that is less than a width of the first region.

2. The semiconductor device of claim 1, wherein walls of the second region of the source and drain converge toward a center point of the source and drain.

3. The semiconductor device of claim 1, wherein a thickness of the second region of the source and drain is self-aligned to a length of the source and drain.

4. The semiconductor device of claim 1, further comprising a wall of the second region of the source and drain indented from an edge of the source and drain toward a centerline of the source and drain.

5. The semiconductor device of claim 4, further comprising a side wall of the gate region, and wherein the side wall of the gate region is positioned relative to the wall of the second region of the source and drain at an angle greater than 90 degrees.

6. The semiconductor device of claim 5, wherein the side wall of the gate region is positioned relative to the wall of the second region of the source and drain at an angle less than 180 degrees.

7. The semiconductor device of claim 1, further comprising one or more side walls of the active region, wherein the side walls terminate on a crystallographic plane having a Miller index of (1,1,1).

8. The semiconductor device of claim 1, wherein the semiconductor device is a multi-gate transistor.

9. A semiconductor device, comprising:
a substrate;
a gate region supported by the substrate, including a first side wall, wherein a first centerline extends axially along a width of the gate region, and a second centerline extends transversely across the first centerline;
a source and drain region positioned transversely to the gate region;
an outer surface of the source and drain region;
a second side wall of the source and drain region; and
a third side wall of the source and drain region, wherein the second side wall and the third side wall are recessed into the source and drain region from the outer surface of the source and drain region.

10. The semiconductor device of claim 9, wherein the second side wall and the third side wall are tapered toward the second centerline of the gate region.

11. The semiconductor device of claim 9, wherein an arrangement of the second side wall and the third side wall defines an indented wall in the source and drain region.

12. The semiconductor device of claim 9, wherein the second side wall and the third side wall converge toward each other toward the second centerline of the gate region.

13. The semiconductor device of claim 9, wherein the second side wall or the third side wall of the source and drain region are positioned at an angle greater than 90 degrees relative to the first centerline of the gate region.

14. The semiconductor device of claim 13, wherein the second side wall or the third side wall of the source and drain region are positioned at an angle less than 180 degrees relative to the first centerline of the gate region.

15. The semiconductor device of claim 9, further comprising a fourth side wall of the source and drain region and a fifth side wall of the source and drain region, wherein the fourth side wall and the fifth side wall taper inward toward a center of the source and drain region, from a side of the second centerline of the gate region opposite the second side wall and the third side wall.

16. The semiconductor device of claim 9, wherein the semiconductor device is a multi-gate transistor.

17. A method of manufacturing a semiconductor device, including:
providing a substrate;
forming a plurality of transistor gate structures on the substrate;
forming a source and drain region positioned adjacent the plurality of transistor gate structures; and
recessing material in the source and drain region toward a centerline of the source and drain region, wherein a width at a center point of the source and drain region is less than an overall width of the source and drain region.

18. The method of claim 17, wherein recessing the material includes isotropically etching the material in the source and drain region inward.

19. The method of claim 17, wherein recessing the material includes crystallographically etching a first side wall and a second side wall of the source and drain region.

20. The method of claim 19 further comprising terminating the etching on a Miller index (1,1,1) crystal plane.
